(19) United States
(12) Patent Application Publication
(10) Pub. No.: US 2026/0114069 A1
(43) Pub. Date: Apr. 23, 2026

(54) LASER PROCESS AND SYSTEM AND RESULTANT ARTICLE OF MANUFACTURE

(71) Applicants: Mool C. Gupta, Keswick, VA (US); Pawan Kumar Kanaujia, Charlottesville, VA (US); University of Virginia Patent Foundation, Charlottesville, VA (US)

(72) Inventors: Mool C. Gupta, Keswick, VA (US); Pawan Kumar Kanaujia, Charlottesville, VA (US)

(21) Appl. No.: 19/120,469

(22) PCT Filed: Oct. 10, 2023
(86) PCT No.: PCT/US2023/076447

§ 371 Date: Apr. 11, 2025

Related U.S. Application Data
(60) Provisional application No. 63/415,202, filed on Oct. 11, 2022.
(60) Provisional application No. 63/538,209, filed on Sep. 13, 2023.

(51) Int. Cl. H10F 71/00

(52) U.S. Cl. CPC H10F 71/134

(57) ABSTRACT

In some aspects, the techniques described herein relate to a method of processing a photovoltaic module structure including multiple layers, the method including: irradiating the photovoltaic module structure with a laser emission to target a specified layer with the laser emission using a specified wavelength of the laser emission; wherein the irradiating includes at least one of: delaminating at least a portion of the specified layer of the photovoltaic module structure from an adjacent layer amongst the multiple layers; or repairing a defect in the specified layer photovoltaic module structure; or both.

### CROSS-REFERENCE TO RELATED APPLICATIONS

This application claims the benefit of priority to U.S. Provisional Patent Application Ser. No. 63/415,202 entitled “LASER PROCESS AND SYSTEM AND RESULTANT ARTICLE OF MANUFACTURE,” filed Oct. 11, 2022, the disclosure of which is incorporated herein in its entirety by reference. The application also claims the benefit of priority to U.S. Provisional Patent Application Ser. No. 63/538,209 entitled “LASER PROCESS AND SYSTEM AND RESULTANT ARTICLE OF MANUFACTURE,” filed Sep. 13, 2023, the disclosure of which is incorporated herein in its entirety by reference.

### BACKGROUND

Solar energy is radiant light and heat from the Sun that is harnessed using a range of technologies such as solar power to generate electricity, solar thermal energy (including solar water heating), and solar architecture. It is an essential source of renewable energy, and its technologies are broadly characterized as either passive solar or active solar depending on how they capture and distribute solar energy or convert it into electric power. Active solar techniques include the use of photovoltaic systems, concentrated solar power, and solar water heating to harness the energy.

### SUMMARY OF THE INVENTION

In some aspects, the techniques described herein relate to a method of processing a photovoltaic module structure including multiple layers, the method including: irradiating the photovoltaic module structure with a laser emission, plasma source, liquid jet, or combination thereof to target a specified layer. For example if a laser emission is used then a laser emission using a specified wavelength of the laser emission can be selected; wherein the irradiating includes at least one of: delaminating at least a portion of the specified layer of the photovoltaic module structure from an adjacent layer amongst the multiple layers; or repairing a defect in the specified layer photovoltaic module structure; or both.

In some aspects, the techniques described herein relate to a method of manufacturing a photovoltaic module structure, the method including: receiving a recycled component of a manufactured cell, the recycled component recovered using laser emission to separate the recycled component from a donor photovoltaic module structure; and incorporating the recycled component into a newly-fabricated photovoltaic module structure or other applications of recycled components.

### BRIEF DESCRIPTION OF THE FIGURES

The drawings illustrate generally, by way of example, but not by way of limitation, various aspects of the present invention.

FIGS. 1A and 1B are exploded views of two different photovoltaic modules.

FIGS. 2A-2C are schematic views of the experimental setup for the laser processing method.

FIG. 3 is a graph showing the optical transmission of glass and ethylene vinyl acetate (EVA).

FIG. 4 is a graph showing a failure profile of typical photovoltaic modules.

FIG. 5 is a schematic view of a process for delaminating a photovoltaic module.

FIGS. 6A-6D are schematic representations of a process for delaminating a photovoltaic module.

FIGS. 7A-7D show a process for using a waterjet in a process for delaminating a photovoltaic module.

FIGS. 8A-8C A process for applying a laser to a bifacial solar module.

FIG. 9 is a view of a recovered glass generated by a delamination process.

### DETAILED DESCRIPTION OF THE INVENTION

Reference will now be made in detail to certain aspects of the disclosed subject matter, examples of which are illustrated in part in the accompanying drawings. While the disclosed subject matter will be described in conjunction with the enumerated claims, it will be understood that the exemplified subject matter is not intended to limit the claims to the disclosed subject matter.

Throughout this document, values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “about 0.1% to about 5%” or “about 0.1% to 5%” should be interpreted to include not just about 0.1% to about 5%, but also the individual values (e.g., 1%, 2%, 3%, and 4%) and the sub-ranges (e.g., 0.1% to 0.5%, 1.1% to 2.2%, 3.3% to 4.4%) within the indicated range. The statement “about X to Y” has the same meaning as “about X to about Y,” unless indicated otherwise. Likewise, the statement “about X, Y, or about Z” has the same meaning as “about X, about Y, or about Z,” unless indicated otherwise.

In this document, the terms “a,” “an,” or “the” are used to include one or more than one unless the context clearly dictates otherwise. The term “or” is used to refer to a nonexclusive “or” unless otherwise indicated. The statement “at least one of A and B” or “at least one of A or B” has the same meaning as “A, B, or A and B.” In addition, it is to be understood that the phraseology or terminology employed herein, and not otherwise defined, is for the purpose of description only and not of limitation. Any use of section headings is intended to aid reading of the document and is not to be interpreted as limiting; information that is relevant to a section heading may occur within or outside of that particular section. A comma can be used as a delimiter or digit group separator to the left or right of a decimal mark; for example, “0.000,1” is equivalent to “0.0001.” All publications, patents, and patent documents referred to in this document are incorporated by reference herein in their entirety, as though individually incorporated by reference. In the event of inconsistent usages between this document and those documents so incorporated by reference, the usage in the incorporated reference should be considered supplementary to that of this document; for irreconcilable inconsistencies, the usage in this document controls.

In the methods described herein, the acts can be carried out in any order without departing from the principles of the invention, except when a temporal or operational sequence is explicitly recited. Furthermore, specified acts can be carried out concurrently unless explicit claim language recites that they be carried out separately. For example, a claimed act of doing X and a claimed act of doing Y can be conducted simultaneously within a single operation, and the resulting process will fall within the literal scope of the claimed process.

The term “about” as used herein can allow for a degree of variability in a value or range, for example, within 10%, within 5%, or within 1% of a stated value or of a stated limit of a range, and includes the exact stated value or range. The term “substantially” as used herein refers to a majority of, or mostly, as in at least about 50%, 60%, 70%, 80%, 90%, 95%, 96%, 97%, 98%, 99%, 99.5%, 99.9%, 99.99%, or at least about 99.999% or more, or 100%.

The term “substantially free of” as used herein can mean having none or having a trivial amount of, such that the amount of material present does not affect the material properties of the composition including the material, such that about 0 wt % to about 5 wt % of the composition is the material, or about 0 wt % to about 1 wt %, or about 5 wt % or less, or less than or equal to about 4.5 wt %, 4, 3.5, 3, 2.5, 2, 1.5, 1, 0.9, 0.8, 0.7, 0.6, 0.5, 0.4, 0.3, 0.2, 0.1, 0.01, or about 0.001 wt % or less, or about 0 wt %.

According to various aspects of the present disclosure, a method of processing a photovoltaic structure (e.g., solar module) is described. Stated more generally, the instant disclosure describes a process for recycling and/or repairing a photovoltaic structure.

The life expectancy of solar modules is about twenty-five years. By 2030, the solar module waste will reach 8 million tons, and by 2050 it will rise to 78 million tons. Currently, there are two approaches for discarding old or broken PV modules; one is to crush the module into powder and separate individual materials for resale or use them for landfill. Currently, most solar modules end up in landfills. The landfill has environmental issues and could contaminate underground water with toxic materials. Significant research has been carried out over the last several decades to improve new solar cell efficiency and decreasing of manufacturing costs. However, very little research has been done on the recycling of old PV modules. The recycling industry needs solutions to help to develop more economical processes that are environmentally friendly for recycling. The proposed solution has particular applicability to Si modules (which constitutes 90%) of the world market. Currently, there is no good method available for the economic recycling of solar panels.

A method proposed herein to solve this problem is laser ablation and or laser melting. Laser ablation is a green process that directly breaks the interfacial bonds for the delamination of glass and does not contaminate the environment. Furthermore, recycled materials could be used for newer solar panel fabrication or other applications. The process will allow the recovery of PV-grade Si wafers and the glass.

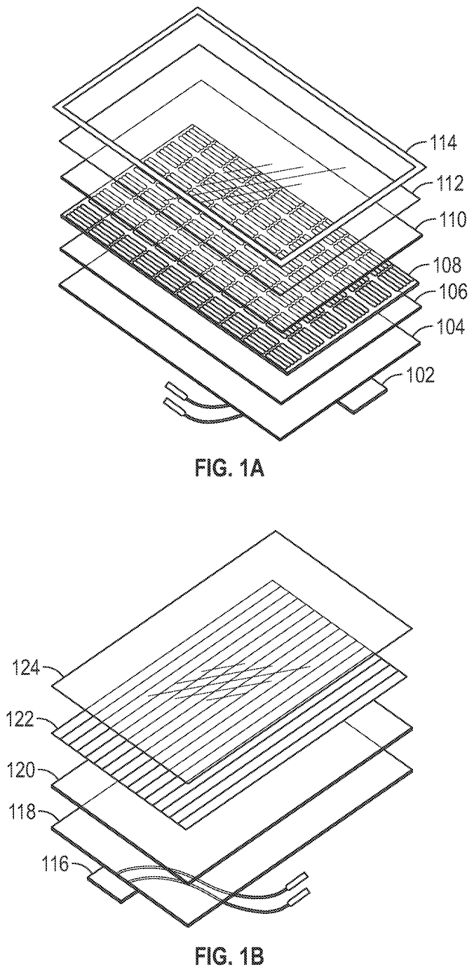

FIGS. 1A and 1B are exploded views of two different photovoltaic modules 100A and 100B. Photovoltaic module 100A includes junction box 102, backsheet 104, first encapsulant 106, solar cell 108, second encapsulant 110, glass 112, and frame 114. Photovoltaic module 100B includes junction box 116, first glass 118, encapsulant 120, solar cell 122, and second glass 124.

In either of photovoltaic modules 100A or 100B, glasses used are any glass material that allows for the transmission of light. Backsheet 104 is typically a polymeric material. Encapsulates 106, 110, and 120 include ethylene vinyl acetate. In various examples, encapsulates 106, 110, and 120 include 80 wt % to 100 wt % ethylene vinyl acetate, 95 wt % to 100 wt % ethylene vinyl acetate, less than, equal to, or greater than 80 wt %, 81, 82, 83, 84, 85, 86, 87, 88, 89, 90, 91, 92, 93, 94, 95, 96, 97, 98, 99, or 100 wt %.

Solar cell 108 or 122 includes a layer of p-type silicon placed next to a layer of n-type silicon. In the n-type layer, there is an excess of electrons, and in the p-type layer, there is an excess of positively charged holes (which are vacancies due to the lack of valence electrons). Near the junction of the two layers, the electrons on one side of the junction (n-type layer) move into the holes on the other side of the junction (p-type layer). This creates an area around the junction, called the depletion zone, in which the electrons fill the holes.

When all the holes are filled with electrons in the depletion zone, the p-type side of the depletion zone (where holes were initially present) now contains negatively charged ions, and the n-type side of the depletion zone (where electrons were present) now contains positively charged ions. The presence of these oppositely charged ions creates an internal electric field that prevents electrons in the n-type layer to fill holes in the p-type layer.

When sunlight strikes a solar cell, electrons in the silicon are ejected, which results in the formation of “holes”—the vacancies left behind by the escaping electrons. If this happens in the electric field, the field will move electrons to the n-type layer and holes to the p-type layer. If you connect the n-type and p-type layers with a metallic wire, the electrons will travel from the n-type layer to the p-type layer by crossing the depletion zone and then go through the external wire back of the n-type layer, creating a flow of electricity.

The methods described herein involve delaminating any of the layers of photovoltaic module 100A or 100B from an adjacent layer; repairing a defect in a specified layer of photovoltaic module 100A or 100B; or both. The method relies on irradiating either photovoltaic module 100A or 100B with a laser emission to target a specified layer with the laser emission using a specified wavelength of the laser emission. The laser emission can be adjustable to select between a range of wavelengths. For example, the specified wavelength of laser emission is selectable from discrete wavelength values falling in a range of from about 300 nm to about 2000 nm, about 350 nm to about 1070 nm, less than, equal to, or greater than about 300 nm, 310, 320, 330, 340, 350, 360, 370, 380, 390, 400, 410, 420, 430, 440, 450, 460, 470, 480, 490, 500, 510, 520, 530, 540, 550, 560, 570, 580, 590, 600, 610, 620, 630, 640, 650, 660, 670, 680, 690, 700, 710, 720, 730, 740, 750, 760, 770, 780, 790, 800, 810, 820, 830, 840, 850, 860, 870, 880, 890, 900, 910, 920, 930, 940, 950, 960, 970, 980, 990, 1000, 1010, 1020, 1030, 1040, 1050, 1060, 1070, 1080, 1090, 1100, 1110, 1120, 1130, 1140, 1150, 1160, 1170, 1180, 1190, 1200, 1210, 1220, 1230, 1240, 1250, 1260, 1270, 1280, 1290, 1300, 1310, 1320, 1330, 1340, 1350, 1360, 1370, 1380, 1390, 1400, 1410, 1420, 1430, 1440, 1450, 1146, 1470, 1480, 1490, 1500, 1510, 1520, 1530, 1540, 1550, 1560, 1570, 1580, 1590, 1600, 1610, 1620, 1630, 1640, 1650, 1660, 1670, 1680, 1690, 1700, 1710, 1720, 1730, 1740, 1750, 1760, 1770, 1780, 1790, 1800, 1810, 1820, 1830, 1840, 1850, 1860, 1870, 1880, 1890, 1900, 1910, 1920, 1930, 1940, 1950, 1960, 1970, 1980, 1990, or 2000 nm.

In addition to controlling the wavelength of the laser emission, the laser can be controlled to irradiate a specific area of photovoltaic module 100A or 100B. The laser can also be configured to scan photovoltaic module 100A or 100B at a predetermined rate. For example, the laser can scan photovoltaic module 100A or 100B at a rate of 5 m/s to 20 m/s, 7 m/s to 15 m/s, less than, equal to, or greater than 5 m/s, 6, 7, 8, 9, 10, 11, 12, 13, 14, 15, 16, 17, 18, 19, or 20 m/s. Additionally, the laser can be configured to pulse, if desired.

The laser can be a conventional laser or the laser can be confided to a column defined by a liquid jet such as a water jet. An advantage of using the water jet is that the laser beam inside the water jet has total reflection and therefore less waste. In some examples, a liquid jet alone can be used to aid in delamination.

In operation, irradiating photovoltaic module 100A or 100B with a laser at a predetermined wavelength causes delamination between selected adjacent layers of photovoltaic module 100A or 100B. By delaminating the adjacent layers, the materials can be recovered with minimal harm to the layers. With the minimal harm caused to the layers and in particular to solar cells 108 or 122, those layers have the opportunity to be recycled and integrated into a new photovoltaic module.

Different layers will be delaminated when exposed to different wavelengths of the laser. For example, a layer including glass and a layer including ethylene vinyl acetate can generally be delaminated when the laser is configured to emit a wavelength of about 300 nm to about 400 nm, about 350 nm to about 340 nm, less than, equal to, or greater than about 300 nm, 305, 310, 315, 320, 325, 330, 335, 340, 345, 350, 355, 360, 365, 370, 375, 380, 385, 390, 395, or about 400 nm. Additionally, a layer including ethylene vinyl acetate and an Si-containing solar cell can be delaminated when the laser is configured to emit a wavelength of about 1000 nm to about 1100 nm, about 1050 nm to about 1070 nm, less than, equal to, or greater than about 1000 nm, 1005, 1010, 1015, 1020, 1025, 1030, 1035, 1040, 1045, 1050, 1055, 1060, 1065, 1070, 1075, 1080, 1085, 1090, 1095, or about 2000 nm.

In some examples, delamination of the layers of photovoltaic module 100A or 100B can be aided using a mechanical biasing element. Examples of mechanical biasing elements can include a rod, a bar, a wire, a razer, or the like. Typically, the mechanical biasing element will be metallic. However, it is possible for the mechanical biasing element to be plastic, ceramic, or a composite of several materials. In some examples it is possible for the mechanical biasing element can be heated. In operation, either the mechanical biasing element or photovoltaic module 100A or 100B are translated orthogonally with respect to the direction of the laser emission. The mechanical biasing element will be positioned to be aligned with the interface between adjacent layer. The mechanical biasing element and photovoltaic module 100A or 100B can be translated orthogonally with respect to the direction of the laser emission concurrently with exposure to the laser emission or following exposure to the laser. The mechanical biasing element can be heated to aid in delaminating. For example, the mechanical biasing element can be heated by exposure to a plasma source.

The laser emission can be used for purposes other than causing delamination. For example, the laser emission can be used to repair a defect in a specified layer of a photovoltaic module 100A or 100B. For example, repairing photovoltaic module 100A or 100B can include reducing a thickness of a layer of the photovoltaic module 100A or 100B, restoring an electrical interconnect, removing a shunt, isolating a defective cell in a module, or a combination thereof.

Reducing the thickness of a layer of photovoltaic module 100A or 100B, is particularly useful for any layer including ethylene-vinyl acetate layer. This is because ethylene-vinyl acetate can be subject to discoloration due to exposure to ultraviolet light as well as from oxygen diffusion. Because most of this damage occurs in the top portion of the layer, reducing the thickness of the layer may remove the damage and extend the life of the photovoltaic module.

Laser emission can be used to remove a shunt in photovoltaic module 100A or 100B. In a photovoltaic module, significant power losses caused by the presence of a shunt resistance, R_{SH}, are typically due to manufacturing defects, rather than poor solar cell design. Low shunt resistance causes power losses in solar cells by providing an alternate current path for the light-generated current. Such a diversion reduces the amount of current flowing through the solar cell junction and reduces the voltage from the solar cell. The effect of a shunt resistance is particularly severe at low light levels, since there will be less light-generated current. The loss of this current to the shunt therefore has a larger impact. In addition, at lower voltages where the effective resistance of the solar cell is high, the impact of a resistance in parallel is large. Shunts can be removed by exposing them to picosecond laser selective scribing of the shunt area.

Damaged electrical interconnects in photovoltaic modules 100A and 100B can be repaired by exposing a damaged electrical interconnect to a relatively longer pulse of laser to allow the damaged interconnect material to melt and reflow to re-establish the electrical connection.

When laser emission is being used to repair photovoltaic modules 100A or 100B care can be taken in selecting the emission wavelength so that any unintended delamination does not occur.

In view of the foregoing, various methods and techniques allow for repair, refurbishing, and/or recycling of photovoltaic modules. Using these methods can extend the operational lifespan of a photovoltaic module relative to a corresponding photovoltaic module that is not subjected to the disclosed method(s). Additionally, delaminated layers of photovoltaic modules 100A or 100B can be incorporated into other photovoltaic modules to produce a photovoltaic module that includes recycled material. In some examples, the produced photovoltaic modules can be composed entirely of recycled delaminated layers.

Following delamination, any layer of the photovoltaic module can be cleaned using a chemical cleaning agent, water, or both. It is to be understood that the methods and techniques described herein can be applied to any photovoltaic module and is not necessarily limited to the photovoltaic modules described herein.

### EXAMPLES

Various aspects of the present invention can be better understood by reference to the following Examples which are offered by way of illustration. The present invention is not limited to the Examples given herein.

### Laser Delamination

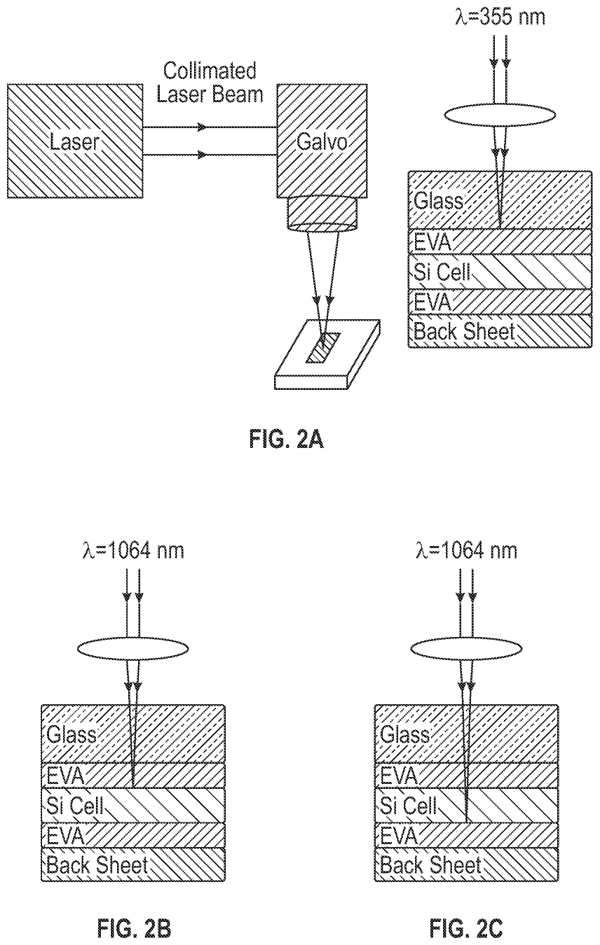

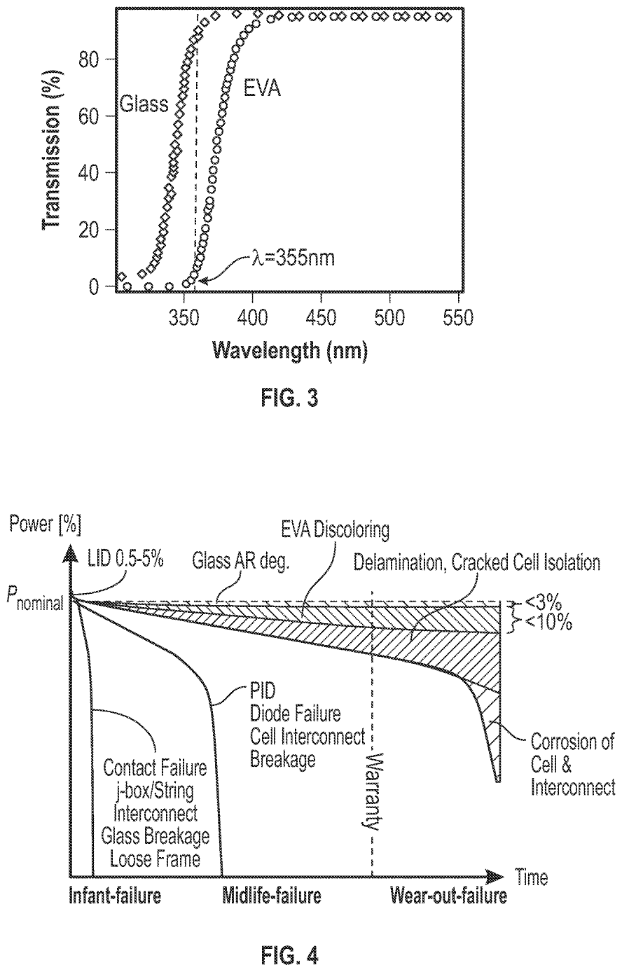

FIGS. 2A-2C shows the schematic of the experimental setup for the laser processing method. A laser wavelength is appropriately will be selected, so the light is absorbed by EVA or Si or back sheet and not by the glass. FIG. 3 shows the optical transmission of glass and EVA, showing that glass will be highly transparent to 355 nm laser wavelength while EVA will absorb the laser light. The use of 355 nm wavelength will allow the UV light decomposition of EVA so it can be separated by a photochemical and photothermal process. The laser pulse width will be selected in the nanosecond range, which will minimize any thermal effect on the surrounding region due to extremely short laser processing times. The laser-generated gaseous products will help further the debonding process. The laser beam will be reshaped from a Gaussian profile to a flat beam profile, and laser processing parameters such as power, focus position, scan speed, and beam overlap will be optimized for the best results. Scanning the laser beam at 10 m/s will allow a faster laser processing time per module.

Two approaches will be considered. The first approach will be to use a pulsed 1064 nm laser. The laser light will be absorbed by the Si wafer generating high temperatures and causing the separation of glass and Si. It will be observed that both Si wafer and glass could be successfully recovered by this method. However, chemical cleaning of the Si wafer is required to remove any laser-generated coating. The second approach will be to use a laser wavelength of 355 nm, and the light will be absorbed by EVA, causing the EVA decomposition and separation of glass. The EVA can be easily removed to recover the Si wafer. The results will show the separation of glass and Si wafer by use of 355 nm laser light.

The glass plate delamination process for solar modules is highly important as it will allow the following: (a) replacement of newly fabricated cracked glass in solar modules, as currently, the entire module is discarded. (b) Replacement of glass for solar modules damaged due to ice, hail, hurricane, tornado, or other weather-related damages. (c) Extraction of high-cost components such as silver, silicon wafers, glass, and metal contact material for end-of-life solar modules. The recycled Si wafer of the photovoltaic grade will be of a superior grade than the metallurgical grade. The method will allow the recovery of glass plate and Si wafers from recycled Si modules. The recovered Si wafers will be able to be reused for the fabrication of higher-efficiency PERC cells without significant processing steps, or the wafer could be cleaned and used for the fabrication of higher efficiency.

### Improvement of Efficiency of Recycled Solar Cells

No permanent damage will occur to delaminated Si wafer, thus allowing them to be recycled. Thus, recycling the layers allows for the remanufacturing of old cells at an efficiency higher than their original design. It is expected that the disclosed process will convert old, recycled silicon solar cells of low efficiency (˜15%) into higher efficiency cells (21%). The recycled Si solar cells have a similarity to the higher efficiency PERC cells. The front surfaces of recycled and PERC cells are exactly the same (Table 1). In recycled Si cells, only the front surface is passivated by depositing a thin layer of SiN, which also acts as an antireflection coating. In a PERC cell, both the front and the back surfaces are passivated.

TABLE 1

| Property | PERC | Al-BSF |
|---|---|---|
| Base thickness μm | 170 | 180 |
| Base resistivity Ω · cm | 2.25 | 2.40 |
| Emitter depth μm | 0.6 | 0.6 |
| Emitter sheet resistance | 80 | 75 |
| Ω/m² | | |
| Front passivation material | PECVD SiNₓ | PECVD SiNₓ |
| Rear passivation material | Al₂O₃ | N/A |
| Front contact paste | PV19L Ag | PV19L Ag |
| Front Gridlines μm | 105-38 | 105-38 |
| Front busbars mm | 4-1.1 | 4-1.1 |
| Rear full contact paste | PV36S Al | MCl206 Al |

For recycled cells, a resin will be screen printed for selective point contacts, and then the metal contact and part on the back surface of Si will be chemically etched away using a 30% KOH solution at 80° C. A dielectric film of Al₂O₃ (10 nm)/SiN (70 nm) will be deposited on the back surface by atomic layer deposition (ALD) and PECVD methods. The resin will be chemically etched away. The metal lines will be screen printed on the back surface to fabricate bifacial cells. The cell front surface will be kept the same, and the back surface will be modified.

### Repairing of Damaged Solar Modules

As noted in FIG. 4, some of the causes of solar module failure include glass breakage, EVA discoloration, photoinduced degradation (PID), and cell and string interconnect breakage and junction shunts. EVA discoloration occurs due to exposure to UV light from the sun and oxygen diffusion. The UV light absorption is governed by Beer's law, so significant absorption occurs in the top surface area. The oxygen will have a significant concentration gradient based on the diffusion equation. So, UV and oxygen diffusion effects will have significant effects on the top part of the EVA. So, removing the top few micron thicknesses would significantly decrease the coloration. The shunts will be isolated by picosecond laser selective scribing of the shunt area, allowing the isolation of the shunt. The interconnects will be repaired by a longer pulse width laser, allowing melting and reflow for repairing interconnect. The photoinduced degradation (PID/is believed to be due to the formation of boron-oxygen complexes. UV light exposure combined with heat, will improve efficiency by a few percent.

Repair experiments will be conducted and shows that it is possible without dismantling the module and allowing the laser beam to be transmitted through the glass. The interconnects will be welded by transmitting and focusing a 450 nm laser wavelength beam through glass and EVA. The shunt areas on the Si wafer will be first determined by photoluminescence and electroluminescence methods, and the identified areas will be isolated by scribing with a laser beam passed through glass and EVA. If we can demonstrate efficiency improvements without any dismantling of the module, this will be major savings and will make recycling even more attractive.

### Solar Component Retrieval Through Mechanical Force and Laser Combination

In this technique, a thin, strong metal wire will be used to facilitate the debonding process of glass and solar cells during laser irradiation. The laser irradiation generates localized heat, leading to the softening of the polymer used to bond the glass and silicon cells. Inserting this wire (which could be hot wire also) at the interface between the glass and silicon cells provided additional support, resulting in the delamination of the solar components.

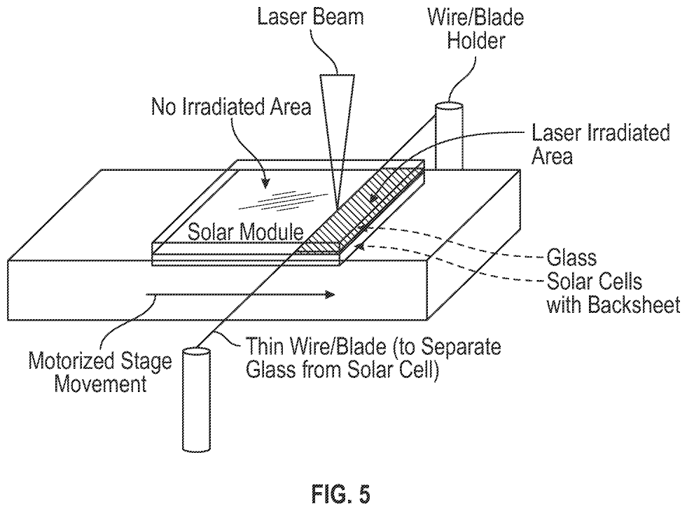

In this example, a solar module is securely mounted on a translational stage, with a taut wire positioned initially at the junction between the glass and silicon cells. A laser beam is directed to scan along the length of the wire, inducing the separation of the polymer adhesive connecting the silicon and glass components. As the laser progresses, the polymer gradually softens, and the translational stage slowly move forward, allowing the wire to insert itself between the glass and silicon, effectively separating them through mechanical force. The process is schematically shown in FIG. 5.

### Direct Back Sheet Removal Using Lasers

Direct laser-assisted backsheet removal will be used. The process begins with laser irradiation of the complete solar module from the topside at glass and silicon interfaces. This localized heat delivery allows weakens the bond between the backsheet and the glass. A mechanical force will be applied to the corners of the module using sharp blades to separate the backsheet from the glass. This further helps to separate the glass along with EVA, and backsheet connected with silicon cells through EVA bonding. In some examples it will be possible to contact the backsheet directly with the laser and not have the laser pass through any glass that may be present.

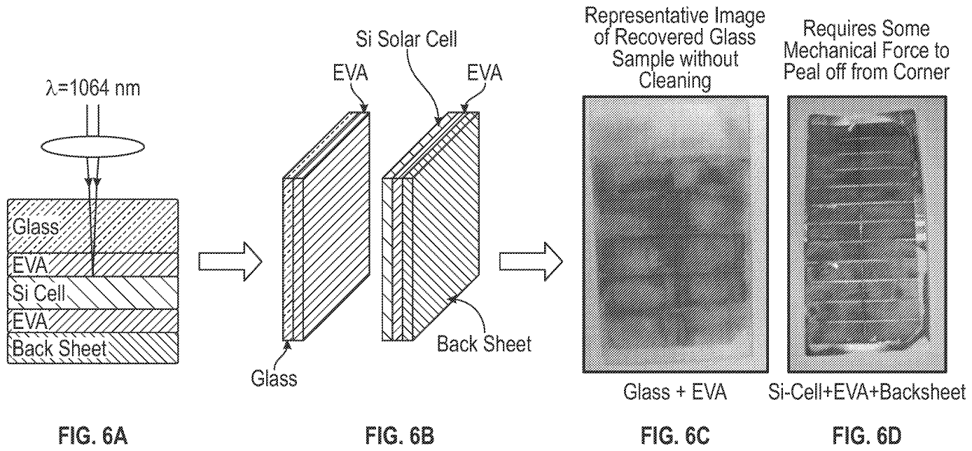

FIGS. 6A-6D are schematic representations of the process: (a) Laser irradiation at the interfaces of Silicon and EVA, (b) Separated components including glass along with EVA and the other component comprising backsheet EVA and silicon cells together, (c) Image of the separated glass with EVA, and (d) Image of the remaining part containing silicon cells, EVA, and backsheet.

Glass Recovery from Solar Modules Using Waterjet Technology

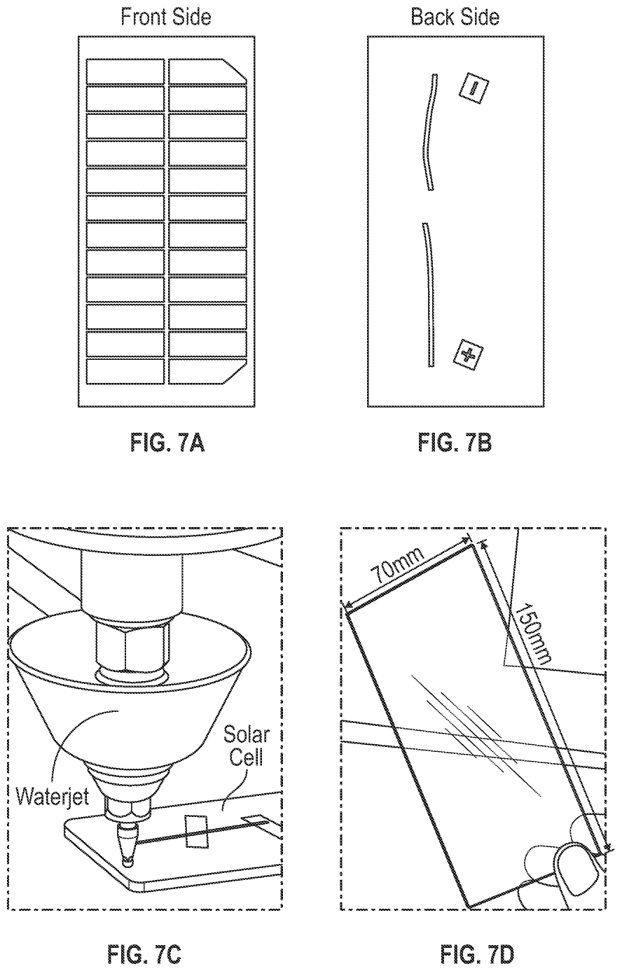

Waterjet technology will be used to recover the solar module glass without damaging it. The waterjet removes the backsheet containing silicon solar cell pieces, freeing up the glass. This allows the glass to be recovered and recycled separately from the other components of the solar module. A commercially available solar module of size 15×7 cm was used and glass was successfully recovered using waterjet technology. In this scenario, the starting solar module is secured to a foam platform, as depicted in FIG. 7C. A water jet will initiate its scanning process across the solar module's surface using carefully calibrated speed and pressure settings. This controlled water jet action effectively removes the backsheet, polymer, and silicon cells while preserving the integrity of the glass component, ensuring no damage occurs (shown in FIG. 7D).

### Application of Laser for Recycling of Bifacial Solar Modules

Glass recovery from bifacial solar modules will be studied. The top glass of a bifacial solar module will be easily recovered using laser irradiation at the interface of the glass and silicon. The laser beam will be focused on the interface between the glass and silicon, and the heat from the laser beam causes the bond between the glass and silicon to break. The top glass can then be easily removed from the module.

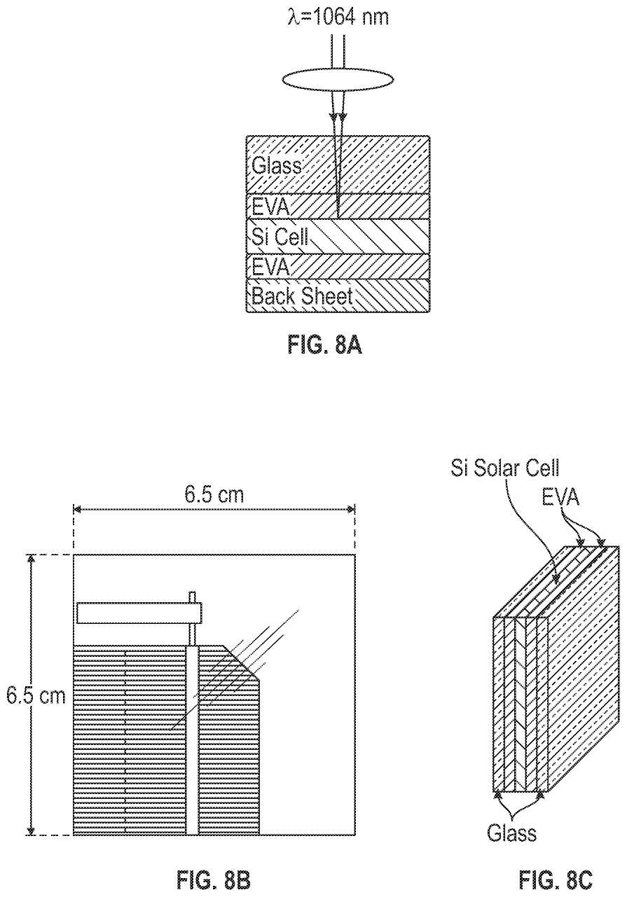

To recover the bottom glass, the laser will again be focused at the interface of the glass and silicon from the glass side. After the debonding process, some mechanical force is required to remove the EVA from the glass. This bottom glass is slightly more difficult to remove than the top glass because the heat from the laser can dissipate more easily to surroundings through the bottom silicon, as there is no other glass layer to block the heat transfer. A process for applying a laser to a bifacial solar module is shown in FIGS. 8A-8C. FIG. 8A schematically shows laser irradiation at the interfaces of silicon and EVA. FIG. 8B is an image of a small portion of a bi-facial solar cell. FIG. 8C is a schematic representation of the structure of the bi-facial solar cells utilized in this recovery process.

Generation of Semitransparent with Microtexture

By precisely directing the laser onto the interfaces of glass and EVA, a semi-transparent glass with a micro-textured back surface. The resulting blackness of the glass is exceptionally durable and resistant to removal even when subjected to chemical, acidic, or alkaline cleaning processes.

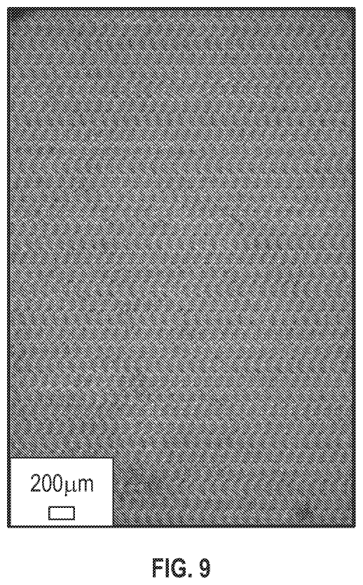

The image of FIG. 9 depicts the rear surface of the recovered glass, revealing a flawless texture on the backside. There is a potential for carbon diffusion into the glass as a result of intense localized heat at the interfaces.

### Exemplary Aspects.

The following exemplary aspects are provided, the numbering of which is not to be construed as designating levels of importance:

Aspect 1 provides a method of processing a photovoltaic module structure comprising multiple layers, the method comprising:
contacting the photovoltaic module structure with a laser emission, a liquid jet, a plasma ray, or a combination thereof to target a specified layer;
wherein the contacting comprises at least one of:
   delaminating at least a portion of the specified layer of the photovoltaic cell structure from an adjacent layer amongst the multiple layers; or
   repairing a defect in the specified layer photovoltaic module structure; or
   both.

Aspect 2 provides the method of Aspect 1, wherein contacting the photovoltaic module comprises irradiating with the laser emission using a specified wavelength of the laser emission.

Aspect 3 provides the method of Aspect 2, wherein the specified wavelength of laser emission is adjustable.

Aspect 4 provides the method of Aspect 3, wherein the specified wavelength of laser emission is selectable from discrete wavelength values falling in a range of from about 300 nm to about 2000 nm.

Aspect 5 provides the method of any of Aspects 3 or 4, wherein the laser emission is selectable from discrete wavelength values falling in a range of from about 350 nm to about 1070 nm.

Aspect 6 provides the method of any of Aspects 1-5, wherein the laser emission is controlled to selectively irradiate specified locations of the photovoltaic module structure.

Aspect 7 provides the method of any of Aspects 1-6, wherein the laser emission is optically confined to a column defined by the liquid jet.

Aspect 8 provides the method of any of Aspects 1-7, wherein the liquid jet comprises a water jet.

Aspect 9 provides the method of any of Aspects 1-8, further comprising:
establishing contact between a biasing element and an interface defined by two layers amongst the multiple layers of the photovoltaic module structure; and
irradiating a region of the interface using the laser emission.

Aspect 10 provides the method of Aspect 9, wherein further comprises heating the biasing element.

Aspect 11 provides the method of any of Aspects 9 or 10, further comprises contacting the photovoltaic module with plasma irradiation.

Aspect 12 provides the method of any of Aspects 10 or 11, comprising translating the region orthogonally with respect to a direct of the laser emission.

Aspect 13 provides the method of any of Aspects 9-12, wherein the biasing element is metallic.

Aspect 14 provides the method of any of Aspects 1-13, wherein the laser emission is directly contacted with a polymeric backsheet of the photovoltaic module.

Aspect 15 provides the method of any of Aspects 1-14, wherein the laser emission does not pass through a glass.

Aspect 16 provides the method of any of Aspects 1-15, wherein the photovoltaic module structure comprises:
a glass layer;
a first ethylene-vinyl acetate layer laminated to the glass layer;
an Si cell laminated to the first ethylene-vinyl acetate layer;
a second ethylene-vinyl acetate layer laminated to the Si cell; and
a polymeric backsheet laminated to the second ethylene-vinyl acetate layer.

Aspect 17 provides the method of any of Aspects 1-16, wherein the delaminated layer of the photovoltaic module structure is recycled.

Aspect 18 provides the method of any of Aspects 1-17, wherein repairing the photovoltaic module structure comprises reducing a thickness of a layer of the photovoltaic module structure, restoring an electrical interconnect, removing a shunt, or a combination thereof.

Aspect 19 provides the method of any of Aspect 16-18, wherein a thickness of the first ethylene-vinyl acetate layer, the second ethylene vinyl acetate layer, or both is reduced.

Aspect 20 provides the method of any of Aspects 18 or 19, wherein restoring an electrical interconnect is accomplished by using the laser irradiation to melt the interconnect and let the melted interconnect reflow and solidify.

Aspect 21 provides the method of any of Aspects 18-20, wherein restoring the electrical interconnect is accomplished substantially without delaminating the manufactured photovoltaic module structure.

Aspect 22 provides the method of any of Aspects 18-21, wherein reducing a thickness of the first ethylene-vinyl acetate layer, the second ethylene vinyl acetate layer, or both decreases discoloration in the first ethylene-vinyl acetate layer, the second ethylene vinyl acetate layer, or both.

Aspect 23 provides a method of processing a photovoltaic module structure comprising multiple layers, the method comprising:
irradiating the photovoltaic module structure with a laser emission optically confined to a column defined by liquid jet comprising a water jet to target a specified layer with the laser emission using a specified wavelength of the laser emission; and
wherein the irradiating comprises at least one of:
   delaminating at least a portion of the specified layer of the photovoltaic module structure from an adjacent layer amongst the multiple layers; or
   repairing a defect in the specified layer photovoltaic module structure; or
   both.

Aspect 24 provides the method of Aspect 23, wherein the specified wavelength of laser emission is adjustable.

Aspect 25 provides the method of Aspect 24, wherein the specified wavelength of laser emission is selectable from discrete wavelength values falling in a range of from about 300 nm to about 2000 nm.

Aspect 26 provides the method of any of Aspects 24 or 25, wherein the laser emission is selectable from discrete wavelength values falling in a range of from about 350 nm to about 1070 nm.

Aspect 27 provides the method of any of Aspects 23-26, wherein the laser emission is controlled to selectively irradiate specified locations of the photovoltaic module structure.

Aspect 28 provides the method of any of Aspects 23-27, further comprising:
establishing electrical contact between a conductor and an interface defined by two layers amongst the multiple layers of the photovoltaic module structure; and
irradiating a region of the electrical contact between the conductor and the interface using the laser emission.

Aspect 29 provides the method of Aspect 28, wherein the irradiating the region of electrical contact comprises heating the conductor.

Aspect 30 provides the method of any of Aspects 28 or 29, comprising translating the region orthogonally with respect to a direct of the laser emission.

Aspect 31 provides the method of any of Aspects 28-30, wherein the conductor is metallic.

Aspect 32 provides the method of any of Aspects 1-31, wherein a pulse width of the laser can be a millisecond scale, microsecond scale, nanosecond scale, picosecond scale, or femtosecond scale.

Aspect 33 provides the method of any Aspects 1-32, wherein a pulse of the laser is a millisecond scale.

Aspect 34 provides the method of any of Aspects 23-33, wherein the photovoltaic module structure comprises:
a glass layer;
a first ethylene-vinyl acetate layer laminated to the glass layer;
an Si cell laminated to the first ethylene-vinyl acetate layer;
a second ethylene-vinyl acetate layer laminated to the Si cell; and
a polymeric backsheet laminated to the second ethylene-vinyl acetate layer.

Aspect 35 provides the method of any of Aspects 23-34, wherein the delaminated layer of the photovoltaic module structure is recycled.

Aspect 36 provides the method of any of Aspects 23-35, wherein repairing the photovoltaic cell structure comprises reducing a thickness of a layer of the photovoltaic module structure, restoring an electrical interconnect, removing a shunt, or a combination thereof.

Aspect 37 provides the method of any of Aspect 34-36, wherein a thickness of the first ethylene-vinyl acetate layer, the second ethylene vinyl acetate layer, or both is reduced.

Aspect 38 provides the method of any of Aspects 36 or 37, wherein restoring an electrical interconnect is accomplished by using the laser irradiation to melt the interconnect and let the melted interconnect reflow and solidify.

Aspect 39 provides the method of any of Aspects 36-38, wherein restoring the electrical interconnect is accomplished substantially without delaminating the manufactured photovoltaic module structure.

Aspect 40 provides the method of any of Aspects 36-39, wherein reducing a thickness of the first ethylene-vinyl acetate layer, the second ethylene vinyl acetate layer, or both decreases discoloration in the first ethylene-vinyl acetate layer, the second ethylene vinyl acetate layer, or both.

Aspect 41 provides the method of any of Aspects 1-40, further comprising cleaning any portion of the photovoltaic module with a chemical cleaning agent, water, or both.

Aspect 42 provides a method of manufacturing a photovoltaic cell structure, the method comprising:
receiving a recycled component of a manufactured module, the recycled component recovered using laser emission to separate the recycled component from a donor photovoltaic cell structure; and
incorporating the recycled component into a newly-fabricated photovoltaic module structure.

Aspect 43 provides the method of Aspect 42, wherein the recycled component is obtained according to the method of any of Aspects 23-41.

Aspect 44 provides a photovoltaic module structure, comprising:
a recycled component obtained by the process of any of Aspects 1-43.

1. A method of processing a photovoltaic module structure comprising multiple layers, the method comprising:
contacting the photovoltaic module structure with a laser emission, a liquid jet, a plasma ray, or a combination thereof to target a specified layer;
wherein the contacting comprises at least one of:
delaminating at least a portion of the specified layer of the photovoltaic cell structure from an adjacent layer amongst the multiple layers; or
repairing a defect in the specified layer photovoltaic module structure; or
both.

2. The method of claim 1, wherein contacting the photovoltaic module comprises irradiating with the laser emission using a specified wavelength of the laser emission.

3. The method of claim 2, wherein the specified wavelength of laser emission is adjustable.

4. The method of claim 3, wherein the specified wavelength of laser emission is selectable from discrete wavelength values falling in a range of from about 300 nm to about 2000 nm.

5. (canceled)

6. The method of claim 1, wherein the laser emission is controlled to selectively irradiate specified locations of the photovoltaic module structure.

7. The method of claim 1, wherein the laser emission is optically confined to a column defined by the liquid jet.

8. (canceled)

9. The method of claim 1, further comprising:
establishing contact between a biasing element and an interface defined by two layers amongst the multiple layers of the photovoltaic module structure; and
irradiating a region of the interface using the laser emission.

10. (canceled)

11. The method of claim 9, further comprises contacting the photovoltaic module with plasma irradiation.

12. (canceled)

13. (canceled)

14. The method of claim 1, wherein the laser emission is directly contacted with a polymeric backsheet of the photovoltaic module.

15. (canceled)

16. The method of claim 1, wherein the photovoltaic module structure comprises:
a glass layer;
a first ethylene-vinyl acetate layer laminated to the glass layer;
an Si cell laminated to the first ethylene-vinyl acetate layer;
a second ethylene-vinyl acetate layer laminated to the Si cell; and
a polymeric backsheet laminated to the second ethylene-vinyl acetate layer.

17. The method of claim 1, wherein the delaminated layer of the photovoltaic module structure is recycled.

18. (canceled)

19. (canceled)

20. (canceled)

21. (canceled)

22. (canceled)

23. A method of processing a photovoltaic module structure comprising multiple layers, the method comprising:
irradiating the photovoltaic module structure with a laser emission optically confined to a column defined by liquid jet comprising a water jet to target a specified layer with the laser emission using a specified wavelength of the laser emission; and
wherein the irradiating comprises at least one of:
delaminating at least a portion of the specified layer of the photovoltaic module structure from an adjacent layer amongst the multiple layers; or
repairing a defect in the specified layer photovoltaic module structure; or
both.

24. The method of claim 23, wherein the specified wavelength of laser emission is adjustable.

25. (canceled)

26. (canceled)

27. The method of claim 23, wherein the laser emission is controlled to selectively irradiate specified locations of the photovoltaic module structure.

28. The method of claim 23, further comprising:
establishing electrical contact between a conductor and an interface defined by two layers amongst the multiple layers of the photovoltaic module structure; and
irradiating a region of the electrical contact between the conductor and the interface using the laser emission.

29. (canceled)

30. The method of claim 23, comprising translating the region orthogonally with respect to a direct of the laser emission.

31. (canceled)

32. (canceled)

33. (canceled)

34. (canceled)

35. The method of claim 23, wherein the delaminated layer of the photovoltaic module structure is recycled or damaged module.

36. The method of claim 23, wherein repairing the photovoltaic cell structure comprises reducing a thickness of a layer of the photovoltaic module structure, restoring an electrical interconnect, removing a shunt, or a combination thereof.

37. (canceled)

38. (canceled)

39. (canceled)

40. (canceled)

41. (canceled)

42. A method of manufacturing a photovoltaic cell structure, the method comprising:
receiving a recycled component of a manufactured module, the recycled component recovered using laser emission to separate the recycled component from a donor photovoltaic cell structure; and
incorporating the recycled component into a newly-fabricated photovoltaic module structure.

43. (canceled)

44. A photovoltaic module structure, comprising:
a recycled component obtained by the process of claim 1.
